(19) United States
(12) Patent Application Publication
(10) Pub. No.: US 2017/0016572 A1
(43) Pub. Date: Jan. 19, 2017

(54) MULTIFUNCTIONAL APPARATUS

(71) Applicant: GFP GESELLSCHAFT FÜR PRODUKTENTWICKLUNG UND PRODUKTIVITÄTSPLANUNG MBH, Öhringen (DE)

(72) Inventors: Alexander Notheis, Karlsruhe Baden (DE); Zoltan Ross, Stuttgart (DE); Siegfried Keusch, Plochingen (DE)

(73) Assignee: GFP GESELLSCHAFT FÜR PRODUKTENTWICKLUNG UND PRODUKTIVITÄTSPLANUNG MBH, Öhringen (DE)

(21) Appl. No.: 15/123,879

(22) PCT Filed: Mar. 4, 2015
(86) PCT No.: PCT/DE2015/100086

§ 371 Date: Sep. 6, 2016

(30) Foreign Application Priority Data
Mar. 4, 2014 (DE) 10 2014 102 865.1
Jul. 8, 2014 (DE) 20 2014 103 136.7
Sep. 8, 2014 (DE) 10 2014 112 910.5
Dec. 24, 2014 (DE) 10 2014 119 631.7

(51) Int. Cl. F16M 13/02; F16M 11/26; F16M 11/20; H05K 7/18; F16M 11/06

(52) U.S. Cl. CPC F16M 13/027; H05K 7/186; F16M 11/06; F16M 11/2078; F16M 11/26; F16M 2200/068

(57) ABSTRACT

Disclosed is a multifunctional apparatus (100) comprising a support (12) which can be moved between a parked position especially a horizontal position and/or a position below the ceiling in a room, and a non-horizontal operational position. In order to further develop said multifunctional apparatus (100) in such a way that same can be reached more easily in the room, the free end of the support (12) that is equipped with supply devices, media devices and/or data devices (24) can be moved three-dimensionally.

### TECHNICAL FIELD

The present invention pertains to a multifunctional apparatus (100) comprising a support (12) which can be moved between a parked position especially a horizontal position and/or a position below the ceiling in a room, and a non-horizontal operational position.

### STATE-OF-THE-ART

Such an apparatus is revealed in the publication EP 1 630 919 A1. The spatial accessibility of such an apparatus is however limited through its pivoting function by merely the horizontal axis, which is disadvantageous, for example, if the tables in an educational institution are arranged in an island configuration, or group-shaped, or circular.

### PRESENTATION OF THE PRESENT INVENTION

### Task, Solution, Advantages

Based on the previously stated disadvantages and shortcomings, as well as with the acknowledgement of the well-defined state of the art, the primary object of the invention is to develop an apparatus of the initially listed type to ensure an improved spatial accessibility.

This task is solved using a multifunctional apparatus with the features listed in claim 1. Advantageous embodiments and practical further formations of the present invention are marked in the sub claims.

The present invention is based on an independently positional apparatus that can be moved around the room three-dimensionally (can also be described as a so-called media lift) with an operating, media, multi-media and/or light terminal that can be moved from a parked or resting position, particularly above about 2.1 meters, to a work or operational position, particularly below approximately 1.6 meters, and which hereby enables an almost circular range within the room, which is advantageous, for example, if the tables in an educational institution are arranged in an island configuration, group-shaped, or circular.

According to a preferred embodiment of the present invention, the apparatus has a support in the type of a pivoting arm, especially one that can be used telescopically and which can be driven linearly, which can be pivoted back and forth between the essentially horizontal parked position or resting position, particularly below the ceiling in a room, and a non-horizontal working position or operating position around an essentially horizontal axis, and whose free end has supply, media, and/or data devices, particularly supply, media and/or data connections in reaching height in the working position or operating position.

The apparatus according to the present invention is intended to provide energy and/or media and/or data in at least one workplace in its working position or operating position, particularly at at least one computer, laboratory, and/or homework station, such as in an educational institution, for example. Several work stations can hereby be connected with each other and/or by means of a central apparatus.

The arm or the support of the apparatus can preferably be pivoted between the horizontally parked position or resting position especially located underneath the ceiling on the one hand, and the non-horizontal working position or operating position around an essentially horizontal axis, and can especially be pivoted outwards from an inclusion unit formed like some type of housing, and be pivoted inwards again into this inclusion unit.

An almost circular range of the supply, media and/or data apparatuses is provided in addition to this linear pivoting ability, preferably by that a joint, particularly a swivel joint, such as a ball joint, for example, is arranged to the end of the support opposing the free end. The apparatus hereby has a significantly increased flexibility as opposed to the state of the art, particularly in the sense of a circular range.

By means of this joint, the support is outside the parked position or resting position, especially when exceeding a specific angular alignment, for example with an alignment of more than 20 degrees from the horizontal, rotatable around a substantially vertical axis, especially in an angular range of about 270 degrees between a first critical angle and a second critical angle.

An especially subdued stop may be intended in the range of the first critical angle and in the range of the second critical angle in an expedited manner, to prevent an exceedance of the first, respectively second critical angle.

The present invention is thus based on a three-dimensional mobility of the apparatus, especially at a level x and y direction (so-called base area) as well at a vertical z direction (also aloft). In a preferential manner, the apparatus can be automatically moved from any desired working position or operating setting, especially at the push of a button, and autonomously into the parked position or resting position.

This way, the terminal can retract with a ceiling height of at least around 2.4 meters above around 2.1 meters, for example, whereby the arm or the support is essentially flush with the terminal, and/or is essentially retractable within the contour of the recording unit, such as a recess or a slot of the recording unit, for example, thus enabling a compact construction height of the apparatus in the parked position or resting position.

The support that is formed in the manner of a pivoting and rotating arm, and which can be operated by an electromotor and/or pneumatics can advantageously comprise of sections or elements that can be slid into each other at least partially telescopically, and that are particularly bendable.

In contrast to the solutions from the state of the art that can merely be used to cover a punctiform, respectively extensive area (=one, or two-dimensional cover), a combination of a rotating and pivoting mechanism, therefore a spatial area, may be used to cover the volume area (=three-dimensional coverage).

The free end of the arm or of the support is provided with the comprised supply and/or data apparatuses that are in a working position or operating position, somewhat at the reaching height, especially on and/or at least one connecting and/or multimedia module, such as connecting, operation and/or multimedia boxes or the connecting, operating and/or multimedia terminal.

This module may be equipped with conventional connections, such as with at least one pressurized air and/or gas connection (with a gas supply that can be switched off in the parked position or resting position of the arm or support, for reasons of safety, for example) with at least one exhaust air connection or at least one (spot) extraction, with at least one water connection (up to the operating height in the media header), with at least one power outlet for power (low voltage, for example, 230 volt, 400 volt) and/or with at least one telecommunication interface for data (such as Ethernet, DVI, HDMI, VGA, audio, video, USB, for example).

For such a wide and comprehensive equipping, it can be advantageous to provide for a cable and line management for gaseous and liquid media, for the electrical power supply (230 volts, for example), for the (telecommunication) data, for the different gases and/or for the pressurized air, meaning for the variety of the available media, so that no cables or lines are visible or accessible at less than 2.1 meters, for example, such as for safety reasons and/or for protection from vandalism.

According to a particularly expedient further formation of the present invention, the module, especially the multimedia terminal can be equipped on both sides.

At least one operating element or operating panel or display or monitor, at least one acoustic element, at least one loudspeaker and/or at least one microphone module for instance, at least one air conditioner, at least one light, at least one mini projector, at least one emergency off button or emergency off switch, at least one control panel for room control, at least one touch display or touch monitor, at least one webcam and/or further pluggable accessories can thus be intended on the front of the module and/or on the back of the module as an integrated accessory.

The connecting, operating and/or multimedia module can particularly be formed replaceable, especially with four to twelve assemblies plus two fittings spaces, optionally with a respective double bottom.

The interchangeability, especially of the coverings or apertures of the module enables a change or expansion of the supply, media, and/or data apparatuses at a later point in time in an advantageous and particularly cost-saving manner.

The supply, media and/or data apparatuses may therefore be combined on and/or in the connection, operating and/or multimedia module in an expedient manner, whereby this particularly height-adjustable and/or rotating formed module can have a flat shape or a flat extension in accordance with a preferred embodiment of the present invention.

To align the module, especially to facilitate the operability of the module and/or to improve the accessibility of the module, it can be arranged in any desired working position or operating position of the apparatus
to be formed pivotal by an essentially vertical first axis for the longitudinal extension of the support, which particularly enables a vertical placement of the module in any desired work position or operating position, and/or
to be pivotal especially at an angular range of around sixty degrees, around an essentially parallel second axis essentially vertical to the first axis for the flat extension of the connecting box

The supply, media and/or data equipment, especially the supply, media and/or data connections can be arranged in a row or in two rows arranged atop each other, for example.

According to an advantageous further formation of the present invention, at least one essentially u-shaped canal that has a profile open towards the top and that can be assembled from sections for the inclusion of cables and lines, particularly the supply, media and/or data cables and lines can be assigned to the apparatus.

This canal, that can be assembled from sections can be covered using at least one lid in an expedient manner. Regardless of this or in connection herewith, the profile of the canal can be provided with at least one connecting point for the inclusion unit and/or for the support.

According to one preferred embodiment of the present invention, leading cables and lines may be installed within the support to the supply, media and/or data equipment, particularly to the supply media and/or data connections, which may be equipped with the cables and lines coming from the ceiling, particularly from the canal in the area of the pivoting/rotating mounting, using connecting elements assigned to the support.

The present invention finally concerns the use of at least one device of the previously listed kind to visualize actions in at least one workplace, especially in at least one computer, laboratory, and/or school workplace, such as an educational institution, for example.

The present invention is therefore preferably used in a room, especially an educational institution, such as a school, for example. Tables are usually set up in this room, especially work tables, such as computer workstations, for example that chairs are arranged to in each case. Due to its three-dimensional mobility, the present invention may hereby be used with a particular benefit, if the tables are arranged in an island-configuration, or group-shaped, or circular.

The installation of the supply, media, and/or data lines to these workplaces may take place using a scaffold-like expandable system comprising at least one canal that runs in longitudinal direction of the room, which is suspended on the ceiling with suspending brackets. The end of the canal can be attached to the back wall of the room with at least one bracket.

The supply, media and/or data lines required for the workstations are laid out in the canal. A support, with a trapezoidal profile, in particular, branches off from the canal on each workplace, which carries the connecting, operating and/or multimedia module equipped with the supply, media and/or data equipment. The related connecting elements, such as a connector or the like can be plugged into their connecting, operating and multimedia connections, which lead to the individual workstations.

It hereby deals with electrical power supply lines and bus systems, but also with data lines that connect the individual workstations with each other, and possibly with a central location, such as a teaching computer, for example.

The canal is arranged at a room height of around 2.5 meters, this means clearly above the reaching height also of tall persons. The supports with the connecting, operating, and/or multimedia modules protrude downwards in the working position or operating position, so that the connecting, operating, and/or multimedia modules are at a height of about 1.6 meters to around 1.8 meters above the floor, the connecting, operating, and/or multimedia connections are therefore also readily accessible for shorter people, without requiring resources in this case.

Besides electrical, supply, data transfer and/or media lines, for example, other cables and lines may also be routed in the canal, especially one or several gas lines and one or several water lines, which will then also lead to supply lines in the connecting, operating and/or multimedia module formed as valves.

The canal may have connected u-shaped profiles that are open upwards. These profiles are closed upwards with detachable, especially lockable lids, which are separated into individual sections. The lines are placed into the profiles forming the canal from the top and are expediently provided with plug connections for the branch lines to the connections of the connection, operating, and/or multimedia module in the area of the supports. It is therefore possible to attach and to also remove the supports attached to the canal from below on the prepared areas.

A provision may be made in a modified embodiment by that the supports comprise telescopic parts that move in relation to each other so that the connection, operating, and/or multimedia module is adjustable aloft (=in vertical Z direction).

To achieve a spatial, mostly complete covering, particularly extensive supply through an (at least almost) circular range, a joint particularly enabling a rotation around a vertical axis can be arranged at the end of the support facing towards the canal.

An especially high degree of flexibility is thus achievable with the present invention, as the devices can be navigated in the room three-dimensionally, meaning not exclusively height-adjustable and not exclusively rigid at one point.

In a favorable manner, at least one locking brake can be intended for the pivoting mechanism. Independent from that or in connection herewith, at least one adjustable pivoting stop may be planned.

It can furthermore be intended that the connection, operating and/or multimedia module itself may be pivotal by a vertical axis so that it can usually be positioned in the most favorable position.

In all embodiments of the media (supply) system according to the present invention, which is especially operated from the ceiling, neither floors nor walls nor the ceilings of a room must be broken open or broken through to install the essentially scaffold-like system.

The system can thus be installed and also removed without significantly changing the respective room. It is thus possible to use the room in a variety of ways.

### SHORT DESCRIPTIONS OF THE DRAWINGS

As already explained beforehand, there are different possibilities to design and furthermore shape the theory of the present invention in an advantageous manner. Reference must hereby be made to the claims subordinate to claim 1 on the one hand; further embodiments, features and benefits of the present inventions are explained in more detail by means of an execution example shown with the drawings on the other hand; possible dimension particulars are to be understood as examples only.

The following is shown:

FIG. 1A a perspective top view onto an execution example of a device according to the present invention;

FIG. 1B a perspective bottom view of the apparatus that is in parked position or resting position from Fig. A;

FIG. 2A a perspective bottom view of the device from FIG. 1B after leaving the parked position or resting position;

FIG. 2B a perspective bottom view of the device that is in working position or operating position from FIG. 2, whereby the terminal box is pivoted both around an essentially vertical first axis that extends longitudinally to the support and also around an essentially vertical second axis that is in parallel to the first axis for the flat extension of the connecting, operating, and/or multimedia module that can be described as the media terminal;

FIG. 3A a schematic visualization of the three-dimensional mobility of the device from FIG. 1A to FIG. 2B in top view;

FIG. 3B a schematic visualization of the three-dimensional mobility of the device from FIG. 1A to FIG. 2B in side view; and

FIG. 3C a perspective visualization of the three-dimensional mobility of the device from FIG. 1A to FIG. 2B.

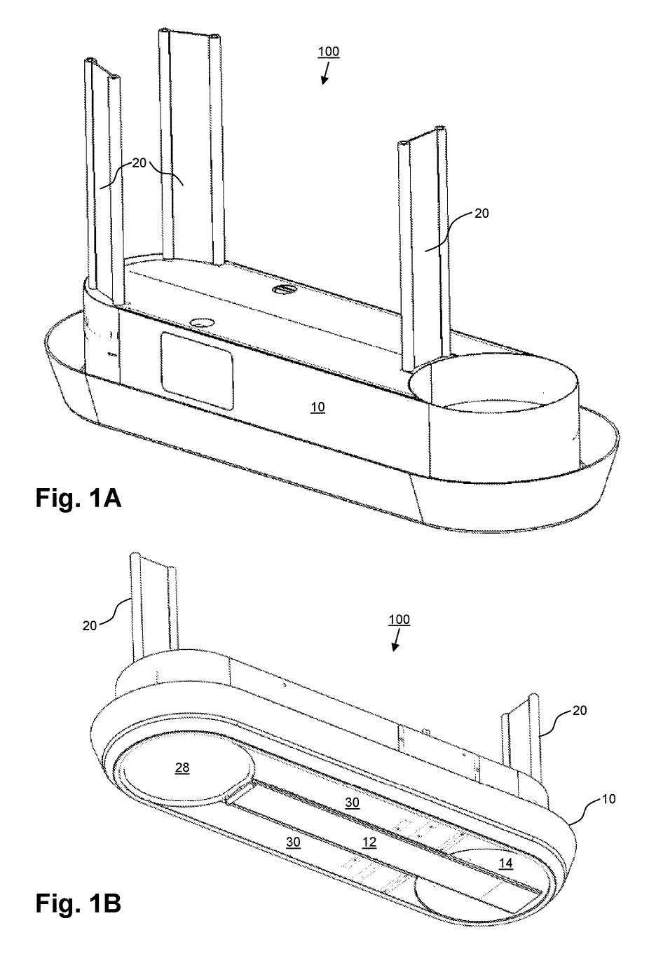

Same or similar embodiments, elements, or features are marked in FIG. 1A to 3C using identical reference signs.

### BEST WAY FOR THE EXECUTION OF THE PRESENT INVENTION

The principal functionality of a ceiling system designed according to a ceiling system in accordance with the present invention to provide supply, media and/or data equipment 24 in at least one workplace, especially in at least one computer, laboratory, and/or school workplace are clarified in FIG. 1A to FIG. 3C.

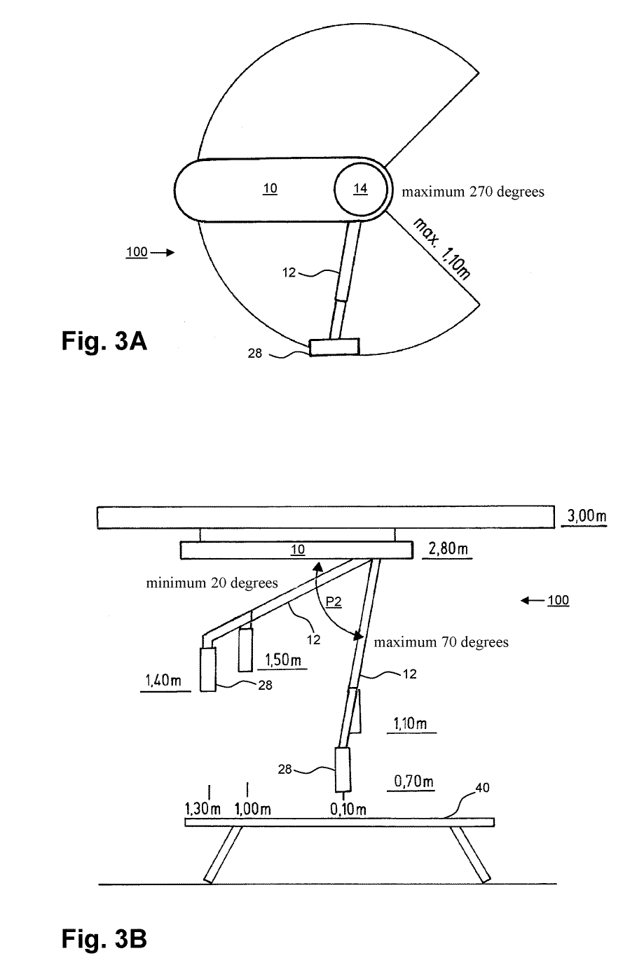

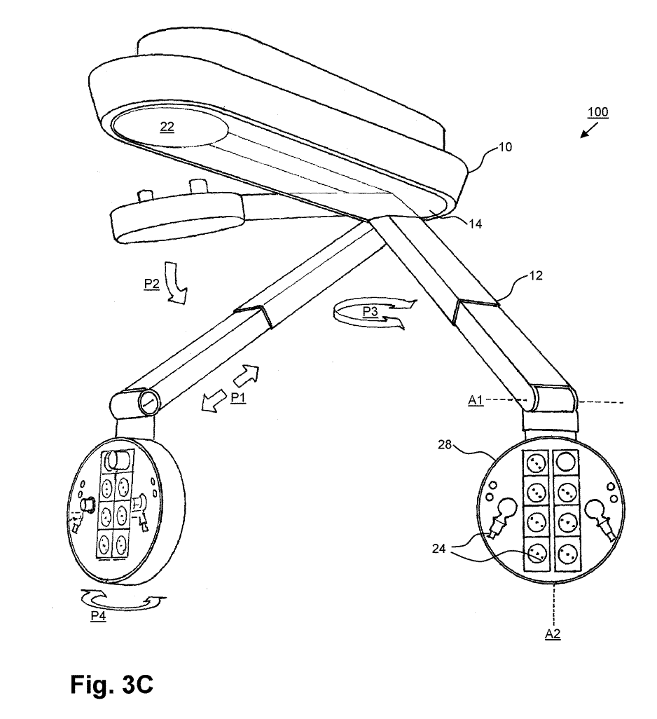

The multifunctional apparatus 100 that can be arranged underneath the ceiling of a room for users staying in a room has a telescopic support 12 formed in the manner of a pivoting and rotating arm. Telescopic means in this connection that the support 12 can be moved linear by about 45 centimeters as indicated by the arrow P1 in FIG. 3C.

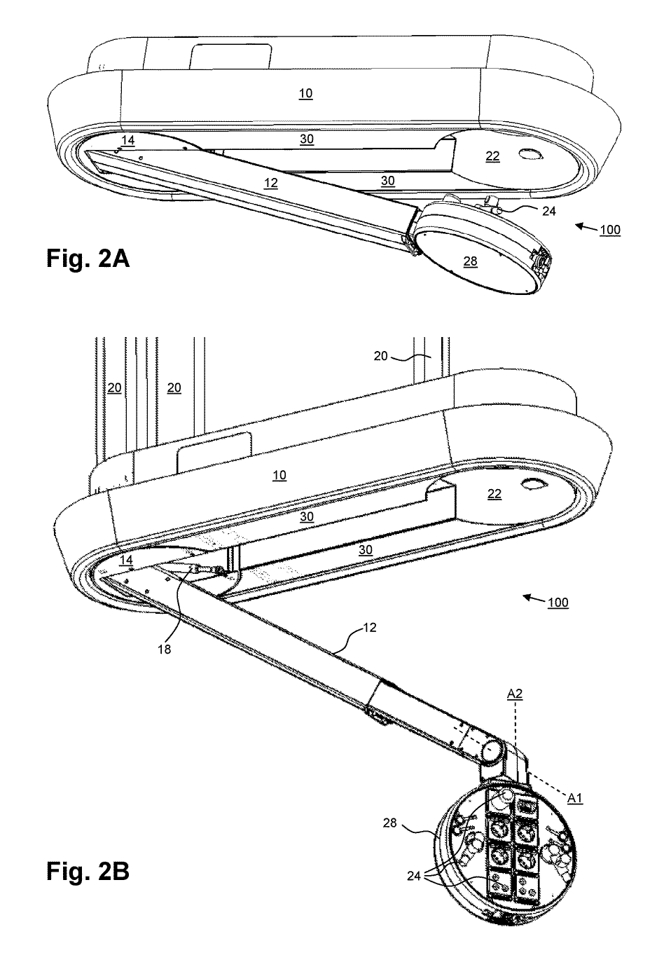

As indicated in FIG. 3B and in FIG. 3C by means of the arrow P2, this support 12 can be moved back and forth between an essentially horizontal parked position or resting position (compare FIG. 1A and FIG. 1B), and a non-horizontal working position or operating position (compare FIG. 2A to FIG. 3C) around an essentially horizontal axis (compare FIG. 3B), whereby the free end of the support 12 comprises the supply, media and/or data apparatuses that are in the working position or operating position at reaching height.

The end of the support 12 that is opposed to the free end of the support 12 is arranged to a swivel joint 14, with which the support 12 outside of the parked position or resting position, particularly when exceeding a specific realignment angle, such as during a realignment of more than about twenty degrees from the horizontal position (compare FIG. 2B to FIG. 3C) can be rotated in an angular range of around 270 degrees (compare FIG. 3A) around an essentially vertical axis, as is indicated through arrow P3 in FIG. 3C.

In the area of the first critical angle definable by +135 degrees, and in the area of a second critical angle definable by −135 degrees, an especially subdued stop is intended in each case, which prevents an exceedance of the first, respectively second critical angle.

The supply, media, and/or data apparatuses 24 are comprised in a box-shaped connection, operating and/or multimedia module (compare FIG. 1B to FIG. 3C), which is formed pivoted around an essentially vertical first axis A1 (compare FIG. 2B and FIG. 3B) around a longitudinal extension of support 12, which enables a vertical placement of the module 28 into any desired working position or operating position.

As is indicated through arrow P4 in FIG. 3C, the module 28 is furthermore formed pivotal, particularly in an angular range of about sixty degrees, around an essentially parallel second axis A2 (compare FIG. 2B and FIG. 3C) for the flat extension of the connection, operating and/or multimedia module.

To enable such a movement of the module 28 in all directions, at least a mountable cable protection coil can be intended within the module 28.

The module 28 can be equipped as an operating panel with an integrated table lighting and/or with an integrated touch display or touch monitor.

As can be gathered from the presentation in FIG. 1A, for example, the support 12 including the module 28 is included in its parked position or resting position in a central inclusion 22 of an inclusion unit 10 formed like some type of console arranged to the ceiling of the room. The support 12 including the module 28 can hereby be retracted from any desired three-dimensional working position or operating position automatically, particularly at the push of a button and autonomously back into the inclusion unit 10.

This inclusion unit 10 is attached to the ceiling of the room by means of three brackets 10 and is formed like some kind of a housing. The swivel joint 14 is housed in this inclusion unit 10.

To light up workplaces or laboratory tables 40 (compare FIG. 3B) underneath the inclusion unit 10, a circumferential lighting 30 is integrated in the inclusion unit 10, particularly something like 500 Lux on the outermost edge of the work table 40 beneath it, in direct and/or indirect LED technology, for example. The inclusion unit 10 hereby optionally has breakthroughs and/or a translucent Plexiglas for the LED light fixtures in the inclusion unit 10.

In order to arrange the cables and lines leading to the supply, media and/or data equipment 24 within the inclusion unit 10 accordingly, the inclusion unit 10 has a mobile deflector shaped as a moveable slide in the form of one or several rolls in the area of the swivel joint 14.

A compensation element 18 is arranged to this slide in the form of a gas pressure spring, whereby this compensation element 18 of the offset caused by the linear procedure of the support of the cables and lines can be compensated within the inclusion unit 10.

Using the apparatus 100 shown in FIG. 1A to FIG. 3C, an extensive media supply can be achieved through a circular range of around 2.2 meters, whereby the apparatus has a particularly high flexibility, because it can be navigated in the room three-dimensionally, meaning not just height-adjustable, and not just rigid in one point.

As is indicated in FIG. 3B, the apparatus per the invention 100 can also be utilized to provide laboratory workplaces with supply lines and with data lines. A measuring device and/or an analytical device with a computer evaluation device may be placed on a laboratory table, for example. The electrical supply lines and the supply lines with gas, water and/or with pressurized air are placed in a canal and branch off on the workplace to the workplace by means of the support 12.

The modular connection box 28 on the free lower end of the support 12 contains the electrical connections, connections for data lines and connections for supply lines for gas, water and/or pressurized air, which the measuring device and/or the analyzer are connected to by means of cables and lines. The connection box 28 can be provided with at least one cable guide so that the cables and/or lines may be placed without interfering on the surface of the table 40.

The apparatus 100 is not necessarily dependent on a canal system attached to the ceiling of the room, but can be suspended on the ceiling in the form of individual console units 10 and is thus best suited for different room concepts. The media supply, especially all the cables and lines up to a height of around 2.2 meters in height may be protected, respectively not be formed accessible for reasons of security.

The device 100 is thus easy to mount and align on different ceiling types, such as on a suspended ceiling, a hollow ceiling, a ribbed floor or on a bare concrete ceiling; in case of a suspended ceiling, a simple wiring duct can thus be intended in case of a suspended ceiling above the same; the same applies to a cover for the suspended ceiling.

Such a simple and cost-effective assembly concept enables a subsequent replacement of cables and a subsequent addition of cables if required, especially in the form of a looping ability from apparatus 100 to apparatus 100.

The modular design in form of the console-type inclusion units 10 generally ensures that the apparatus 100 can also easily be supplemented and/or retrofitted and/or can be scaled to size subsequently without a problem in case of a changing media requirement or changing safety regulations, for example, such as in case of a spatial expansion.

Through the combination of the pivoting and rotation mechanism for the support 12 which is retractable and expandable with an electric motor, a simple and flexible adaptation of the apparatus 100 to different room heights and an ergonomic height adjustment are possible without a problem; the apparatus 100 can especially be used for room heights between around 2.4 meters to around 4 meters.

In case of need, such as in case of emergency and/ or with a power outage, for example, the apparatus 100, and particularly its support 12 can also be moved and rotated manually. The apparatus 100 is generally characterized by a very sturdy construction, such as through a load capacity of up to around 150 kilograms, which seems very beneficial in case of a possible improper use of the apparatus 100 in an educational facility.

At least one lever brake and/or at least one adjustable pivoting stop may be intended for the pivoting mechanism as a further safeguard against an overload or even vandalism.

Teachers will come to appreciate the very short set-up time, meaning the very quick availability of the apparatus 100 within of a maximum of around ten seconds, so that there won't be any unrest in the classroom. The ergonomic availability of the media at a maximum operating height of around 1.8 meters in the connection box or media terminal 28 also allows a problem-free working and researching with the apparatus 100 for any person who hasn't quite fully grown physically.

### List of reference signs

100 Apparatus
10 Inclusion unit
12 Support
14 Joint, especially rotating joint, such as a ball joint, for example
18 Compensation element, especially gas pressure spring
20 Mount or bracket, especially ceiling mount or ceiling bracket
22 Recess or opening of the inclusion unit 10
24 Supply, media and/or data apparatuses
28 Connection, operating and/or multimedia module, especially connection, operating and or multimedia box or connection, operation, and/or multimedia terminal
30 Lighting element
40 Table, especially work table or laboratory table, at a workplace such as a computer workplace, for example.
A1 First axis
A2 Second axis
P1 First arrow
P2 Second arrow
P3 Third arrow
P4 Fourth arrow

1. Multifunctional apparatus (100) comprising a mobile support (12) between a particularly horizontal parked position and/or intended underneath the ceiling of a room and a non-horizontal work position, whereby the free end of the support (12) comprising the supply, media, and/or data apparatuses (24) can be moved three-dimensionally.

2. Apparatus according to claim 1, characterized in that the end of the support (12) opposing the free end is arranged to a joint (14), especially a rotating joint, such as a ball joint, for example.

3. Apparatus according to claim 1 or 2, characterized in that the support (12) is formed like some type of a pivoting arm that can be moved back and forth around an essentially horizontal axis, which can be rotated around an essentially vertical axis outside of the parked position, especially when exceeding a certain angle of the pivoting from the horizontal position, such as when pivoting more than around twenty degrees from the horizontal position.

4. Apparatus according to claim 3, characterized in that the support (12) can be rotated at an angular range, especially of about 270 degrees, between a first critical angle and a second critical angle.

5. Apparatus according to claim 4, characterized in that an especially subdued stop is intended in the area of the first critical angle and in the area of the second critical angle that prevents an exceeding of the first, respectively second critical angle.

6. Apparatus according to at least one of the claims 1 to 5, characterized in that the support (12) can be moved telescopically, especially linearly.

7. Apparatus according to at least one of the claims 1 to 6, characterized in that the supply, media, and/or data equipment (24) in the working position are at a reaching height.

8. Apparatus according to at least one of the claims 1 to 7, characterized in that the supply, media and/ or data equipment (24) are comprised on and/or in at least one connection, operating, and/or multimedia module (28).

9. Apparatus according to claim 8, characterized in that the connection, operating, and/or media module (28)
is formed pivotal around an essentially vertical first axis (A1) to the longitudinal extension of the support (12), and/or,
especially at an angular range of around sixty degrees, is formed pivotal around an essentially parallel second axis (A2) around an essentially vertical extension of the connection, operating and/or multimedia module (28) around a first axis.

10. Apparatus according to at least one of the claims 1 to 9, characterized in that the support (12) especially including the connection, operating and/or multimedia module can be moved back to the parked position from any working position.

11. Apparatus according to at least one of the claims 1 to 10, characterized in that the support (12) in its parked position can be included, at least partially, especially completely and/or including the connection, operating, and/or multimedia module (28), in an inclusion unit, especially arranged to the ceiling of a room, such as by means of a bracket (20) on the ceiling of a room, especially in a recess or opening (22) of the inclusion unit (10), for example.

12. Apparatus according to claim 11, characterized in that,
the inclusion unit (10) is formed in a manner of a housing and/or
that the inclusion unit (10) comprises the joint (14) and/or
that the inclusion unit (10) comprises at least one particularly circumferential lighting element (30), especially for lighting up at least one work place, particularly of at least one computer, laboratory, and/or schoolwork place in an educational institution.

13. Apparatus according to at least one of the claims 1 to 12, characterized by lines that lead through the areas of the joint (14) through at least one mobile slide, especially through at least one mobile deflector formed as a roll, within the column (12) to the supply, media and/or data equipment (24), especially for electrical power and/or for data signals, such as for telecommunication signals, for example, and/or for at least one liquid medium, such as for water, for example, and/or for at least one gaseous medium such as pressurized air, for example.

14. Apparatus according to claim 13, characterized in that the lines are housed in the support (12), particularly including the inclusion unit (10) and/or including the connection, operating, and/or multimedia module (28).

15. Apparatus according to claim 13 or 14, characterized by at least one compensation element (18) arranged to the slide, especially at least one gas pressure spring, to compensate the offset of the lines caused by the linear process of the support (12), +especially within the inclusion unit (10).
